(19) United States
(12) Patent Application Publication
(10) Pub. No.: US 2023/0411558 A1
(43) Pub. Date: Dec. 21, 2023

(54) LIGHT EMITTING DEVICE, OPTICAL DISTANCE-MEASURING DEVICE, AND IMAGE FORMING APPARATUS

(71) Applicant: FUJIFILM Business Innovation Corp., Tokyo (JP)

(72) Inventors: Shigetoshi NAKAMURA, Kanagawa (JP); Kazuhiro SAKAI, Kanagawa (JP); Hiroyuki HOTTA, Kanagawa (JP); Kei TAKEYAMA, Kanagawa (JP); Yoshihiro YAMAMOTO, Kanagawa (JP); Junichiro HAYAKAWA, Kanagawa (JP)

(73) Assignee: FUJIFILM Business Innovation Corp., Tokyo (JP)

(21) Appl. No.: 17/978,330

(22) Filed: Nov. 1, 2022

(30) Foreign Application Priority Data
Jun. 15, 2022 (JP) 2022-096859

(51) Int. Cl. H01L 33/08; H01L 33/58; G02B 3/06; G02B 9/12

(52) U.S. Cl. CPC H01L 33/08; H01L 33/58; G02B 3/06; G02B 9/12

(57) ABSTRACT

A light emitting device includes: a light emitting part having multiple light emitting regions arranged along a first direction; and an optical system that is disposed on a light-exit side of the light emitting part and that deflects light emitted from the multiple light emitting regions in different directions, the optical system being configured such that a light exit angle in a second direction, which intersects the first direction, is smaller than the light exit angle in the first direction.

### CROSS-REFERENCE TO RELATED APPLICATIONS

This application is based on and claims priority under 35 USC 119 from Japanese Patent Application No. 2022-096859 filed Jun. 15, 2022.

### BACKGROUND

### (i) Technical Field

The present disclosure relates to a light emitting device, an optical distance-measuring device, and an image forming apparatus.

### (ii) Related Art

Japanese Patent No. 4427954 discloses a monitoring device in which a projection lens is disposed so as to face a vertical cavity surface emitting laser (VCSEL) array having multiple laser diodes arranged two-dimensionally. The monitoring device two-dimensionally scans an object to be monitored.

Japanese Patent No. 5257053 discloses an optical scanning device including a laser-array light source, a condenser lens that converges laser light, and a movable mirror that reflects the converged laser light to illuminate a surface to be scanned. The optical scanning device scans a surface to be scanned with the laser light.

Japanese Patent No. 6965784 discloses a distance measuring device including a light source and a light scanning part including a micro mirror. The distance measuring device performs scanning with a light beam.

### SUMMARY

A practically used optical distance-measuring device measures the distance to an object located in a scanning range by scanning, in a first direction, light emitted from a light emitting device and detecting reflected light. The light emitting device includes a light emitting part having multiple light emitting regions arranged in the first direction, and an optical system for deflecting the light emitted from the multiple light emitting regions in different directions.

However, in this optical distance-measuring device having the light emitting device, if the light emitted from the light emitting device is diffused not only in the first direction, but also in the second direction, the diffused light exits also in the second direction at a certain scanning position, potentially affecting the measurement of the distance to the object.

Aspects of non-limiting embodiments of the present disclosure relate to providing a light emitting device in which the amount of light diffused in the second direction is reduced, and an optical distance-measuring device and an image forming apparatus having this light emitting device. Aspects of certain non-limiting embodiments of the present disclosure address the above advantages and/or other advantages not described above. However, aspects of the non-limiting embodiments are not required to address the advantages described above, and aspects of the non-limiting embodiments of the present disclosure may not address advantages described above.

According to an aspect of the present disclosure, there is provided a light emitting device including: a light emitting part having multiple light emitting regions arranged along a first direction; and an optical system that is disposed on a light-exit side of the light emitting part and that deflects light emitted from the multiple light emitting regions in different directions, the optical system being configured such that a light exit angle in a second direction, which intersects the first direction, is smaller than the light exit angle in the first direction.

### BRIEF DESCRIPTION OF THE DRAWINGS

Exemplary embodiments of the present disclosure will be described in detail based on the following figures, wherein:

FIG. 1 is an external view schematically showing the configuration of an image forming apparatus according to a first exemplary embodiment;

FIG. 2 shows a situation in which an optical distance-measuring device detects a user who is approaching to use the image forming apparatus;

FIG. 3 schematically shows the configuration of the optical distance-measuring device;

FIG. 4 schematically shows the configuration of a VCSEL array;

FIG. 5 is an X-Z plane projection showing the configuration of an optical system;

FIG. 6 is a Y-Z plane projection showing the configuration of the optical system;

FIG. 7 is an X-Z plane projection showing the configuration of an optical system having equal refractive powers in the X-axis direction and in the Y-axis direction;

FIG. 8 is a Y-Z plane projection showing the configuration of the optical system having equal refractive powers in the X-axis direction and in the Y-axis direction;

FIG. 9 shows the effect of the optical distance-measuring device;

FIG. 10 is an external view schematically showing the configuration of a human sensing gate according to a second exemplary embodiment;

FIG. 11 is an X-Z plane projection showing the configuration of an optical system in Example 1;

FIG. 12 is a Y-Z plane projection showing the configuration of the optical system in Example 1;

FIG. 13 is an X-Z plane projection showing the configuration of an optical system in Example 2;

FIG. 14 is a Y-Z plane projection showing the configuration of the optical system in Example 2;

FIG. 15 is an X-Z plane projection showing the configuration of an optical system in Example 3;

FIG. 16 is a Y-Z plane projection showing the configuration of the optical system in Example 3;

FIG. 17 is a table of average and standard deviation of measurement results for respective light emitting regions in Examples 1 to 3 and a comparison example;

FIG. 18 is graph plotted from the table in FIG. 17;

FIG. 19 is a graph showing the number of rays for each of the total optical path lengths of six light emitting regions in Example 1;

FIG. 20 is a graph showing the number of rays for each of the total optical path lengths of the six light emitting regions in Example 2;

FIG. 21 is a graph showing the number of rays for each of the total optical path lengths of the six light emitting regions in Example 3; and

FIG. 22 is a graph showing the number of rays for each of the total optical path lengths of the six light emitting regions in a comparison example.

### DETAILED DESCRIPTION

### First Embodiment

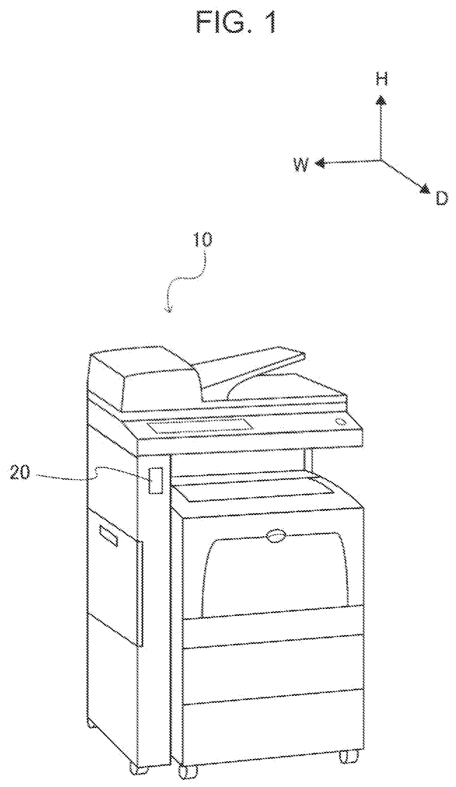

Overall Configuration of Image Forming Apparatus The first exemplary embodiment of the present disclosure will be described in detail below with reference to the drawings. FIG. 1 is an external view schematically showing the configuration of an image forming apparatus 10 according to the first exemplary embodiment of the present disclosure. The W, H, and D axes in FIG. 1 are coordinate axes of the image forming apparatus 10. The W-axis direction is the horizontal direction corresponding to the width direction of the apparatus, the H-axis direction is the vertical direction corresponding to the top-bottom direction of the apparatus, and the D-axis direction is the horizontal direction corresponding to the depth direction of the apparatus.

As shown in FIG. 1, the image forming apparatus 10 is a so-called multi-function machine having multiple functions, including a printing function, a scanning function, a copying function, and a facsimile function. The image forming apparatus 10 has an optical distance-measuring device 20 that serves as a human sensor for detecting a user who is going to use the image forming apparatus 10.

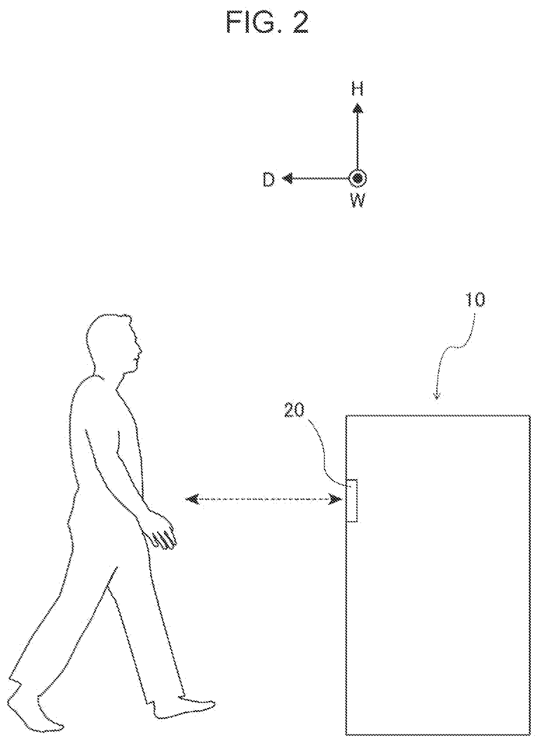

FIG. 2 shows a situation in which the optical distance-measuring device 20 detects a user who is approaching to use the image forming apparatus 10. As shown in FIG. 2, because a user typically approaches the position where the image forming apparatus 10 is installed, the optical distance-measuring device 20 is set so as to detect such a user.

In the image forming apparatus 10 according to this exemplary embodiment, for example, when a user who intends to use the image forming apparatus 10 is detected with the optical distance-measuring device 20, control to return the image forming apparatus 10 from an energy-saving state to a normal operation state is performed.

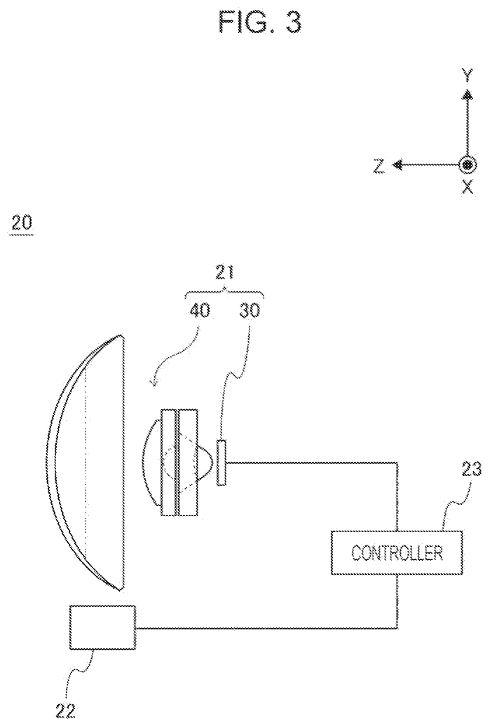

Configuration of Optical Distance-Measuring Device FIG. 3 schematically shows the configuration of the optical distance-measuring device 20 according to this exemplary embodiment. The X, Y, and Z axes in FIG. 3 are perpendicular to one another and serve as the coordinates of the optical distance-measuring device 20. The X-axis direction corresponds to a first direction in the technology of the present disclosure. The Y-axis direction is an example of a second direction intersecting the first direction and corresponds to a second direction in the technology of the present disclosure.

As shown in FIG. 3, the optical distance-measuring device 20 includes a light emitting device 21 that emits measurement light, a photo detector (PD) 22 that detects reflected light of the light emitted from the light emitting device, and a controller 23. The PD 22 is an example of a detector in the technology of the present disclosure.

The light emitting device 21 includes a VCSEL array 30 and an optical system 40. The VCSEL array 30 is an example of a light emitting part in the technology of the present disclosure.

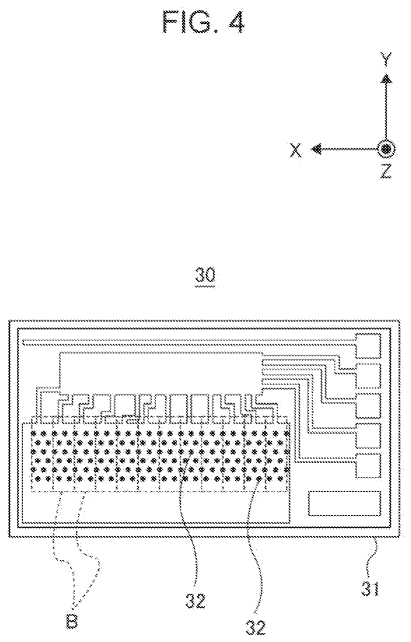

FIG. 4 schematically shows the configuration of the VCSEL array 30. As shown in FIG. 4, the VCSEL array 30 has a configuration in which multiple VCSEL light emitting elements 32 are arranged on a substrate 31, at equal intervals in a staggered pattern. Compared with a case where the light emitting elements 32 are arranged in matrix, the light emitting elements 32 are arranged with a higher density.

The VCSEL array 30 has multiple light emitting regions B arranged along the X-axis direction. The VCSEL array 30 is configured such that multiple light emitting elements 32 are provided in one light emitting region B and such that, in one light emitting region B, the number of the light emitting elements 32 arranged in the Y-axis direction is greater than the number of the light emitting elements 32 arranged in the X-axis direction. The light emitting regions B have a rectangular shape, whose length in the Y-axis direction is greater than that in the X-axis direction. Because the multiple light emitting regions are arranged in the X-axis direction, the multiple light emitting regions B of the VCSEL array 30 together form a rectangular shape, whose length in the X-axis direction is greater than that in the Y-axis direction. On/off of the light emitting elements 32 of the VCSEL array 30 is controlled for each light emitting region B.

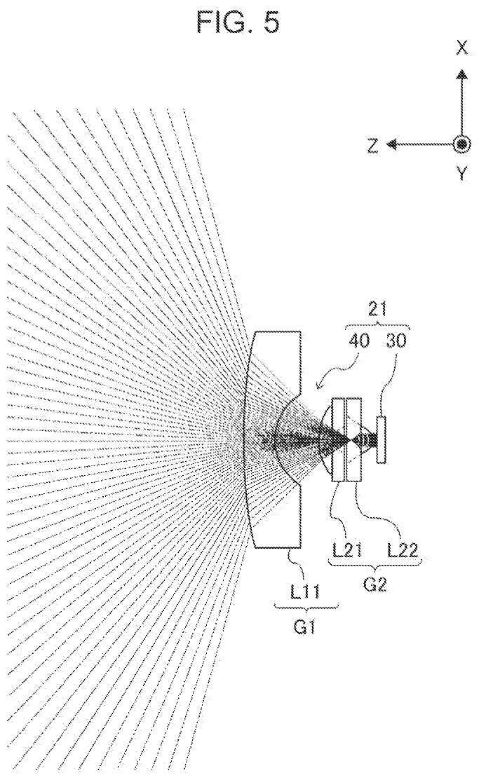

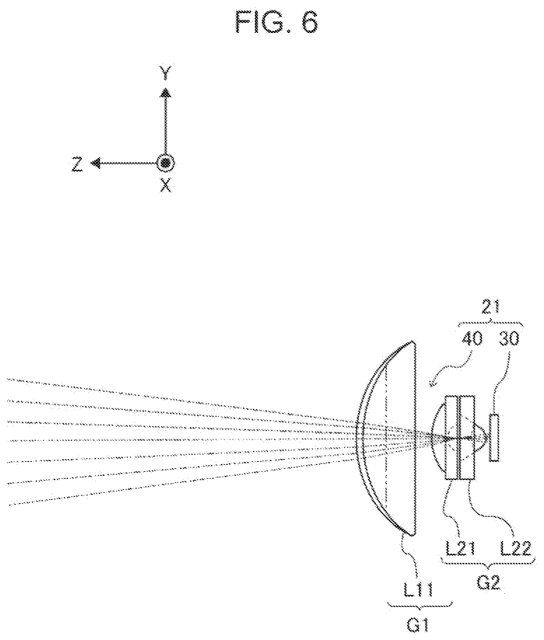

FIG. 5 is an X-Z plane projection showing the configuration of the optical system 40. FIG. 6 is a Y-Z plane projection showing the configuration of the optical system 40. In FIGS. 5 and 6, the left side is the light exit side, and the right side is the light entrance side. FIGS. 5 and 6 show the position of the VCSEL array 30 with respect to the optical system 40. Furthermore, FIGS. 5 and 6 also show the optical paths of rays emitted from the VCSEL array 30.

As shown in FIGS. 5 and 6, the optical system 40 is an optical system that is disposed on the light-exit side of the VCSEL array 30 and that deflects the light emitted from the multiple light emitting regions B in different directions. The optical system 40 is configured such that the light exit angle in the Y-axis direction is smaller than the light exit angle in the X-axis direction.

Herein, when diffused light emitted from one point and having an isotropic diffusion property passes through and exits the optical system 40, the light exit angle in the Y-axis direction is smaller than the light exit angle in the X-axis direction. The diffusion property as discussed herein is equivalent to divergence, which is a property of light in which light emitted from one point propagates while spreading.

In this exemplary embodiment, for example, the optical system 40 includes three lenses, namely, lenses L11, L21, and L22.

In this exemplary embodiment, the optical system 40 may be configured to include a lens having a toroidal surface that has curvature in the X-axis direction and in the Y-axis direction, the radius of curvature in the Y-axis direction being smaller than that in the X-axis direction. In the example in FIGS. 5 and 6, the light-exit-side surface of the lens L11 has a toroidal shape in which the radius of curvature in the Y-axis direction is smaller than the radius of curvature in the X-axis direction. The definition of the curvature of a lens is as below: the curvature in the X-axis direction is the curvature with the axis of rotation being the Y axis, and the curvature in the Y-axis direction is the curvature with the axis of rotation being the X axis. The greater the curvature is, the smaller the arc is, i.e., the smaller the radius of curvature is, and the smaller the curvature is, the greater the arc is, i.e., the greater the radius of curvature is.

Furthermore, the optical system 40 may be configured to include a lens having a cylindrical surface that has curvature in the X-axis direction and no curvature in the Y-axis direction. In the example in FIGS. 5 and 6, the light-entrance-side surface of the lens L11 has a cylindrical shape that has curvature in the X-axis direction and no curvature in the Y-axis direction.

Furthermore, the optical system 40 may be configured to include, in order from the light exit side to the light entrance side, a first lens group and a second lens group. The largest air spacing is provided between the first lens group and the second lens group. The first lens group has, as a whole, a negative refractive power in the first direction and a positive or no refractive power in the second direction. In the example in FIGS. 5 and 6, the optical system 40 includes, in order from the light exit side to the light entrance side, a first lens group G1 and a second lens group G2. In this example, the light exit angle in the Y-axis direction, which intersects the X-axis direction, is made smaller than the light exit angle in the X-axis direction by adjusting the refractive power of the lenses.

In this case, it is desirable that the first lens group G1 include a single lens, L11. When the first lens group G1 includes the single lens, L11, the light-exit-side surface of the lens L11 may have a toroidal shape, and the light-entrance-side surface of the lens L11 may have a cylindrical shape. Alternatively, the light-exit-side surface and the light-entrance-side surface of the lens L11 may have toroidal shapes.

Furthermore, the second lens group G2 may be configured to have, as a whole, a negative refractive power in the X-axis direction and a positive or no refractive power in the Y-axis direction. Furthermore, the second lens group G2 may be configured to have, as a whole, equal refractive powers in the X-axis direction and in the Y-axis direction. Furthermore, it is desirable that the second lens group G2 include two lenses. In the example in FIGS. 5 and 6, in the optical system 40, the second lens group G2 includes two lenses, namely, the lenses L21 and L22, and the refractive power in the X-axis direction and the refractive power in the Y-axis direction are equal.

The controller 23 includes a CPU, a memory, a storage, and the like. The controller 23 controls the operation of the light emitting device 21 and the PD 22, and performs processing of calculating the distance between the light emitting device 21 and an object to be measured, on the basis of a signal detected by the PD 22.

More specifically, the controller 23 controls the VCSEL array 30 such that light is sequentially emitted from one side of the multiple light emitting regions B arranged in the X-axis direction and scanned in the X-axis direction. Next, the controller 23 causes the PD 22 to detect reflected light of the light emitted from the light emitting regions B. Next, the controller 23 calculates the time difference between the time when the light is emitted from the light emitting regions B and the time when the PD 22 detects the reflected light, on the basis of the signal detected by the PD 22. Next, the controller 23 calculates the distance between the light emitting device 21 and the object to be measured in a detection area corresponding to each light emitting region B, on the basis of the calculated time difference.

The light emitting device 21 of the optical distance-measuring device 20 is disposed such that, in the image forming apparatus 10, the X-axis direction thereof corresponds to the horizontal direction of the image forming apparatus 10, and the Y-axis direction thereof corresponds to the vertical direction of the image forming apparatus 10.

### Operation of Light Emitting Device, Optical Distance-Measuring Device, and Image Forming Apparatus

As shown in FIGS. 5 and 6, the optical system 40 is configured such that the light exit angle in the Y-axis direction is smaller than the light exit angle in the X-axis direction.

As shown in FIG. 5, in the X-axis direction, the exit angle of the light emitted from the VCSEL array 30 and passing through the optical system 40 is wide. In contrast, as shown in FIG. 6, in the Y-axis direction, the exit angle of the light emitted from the VCSEL array 30 and passing through the optical system 40 is narrow.

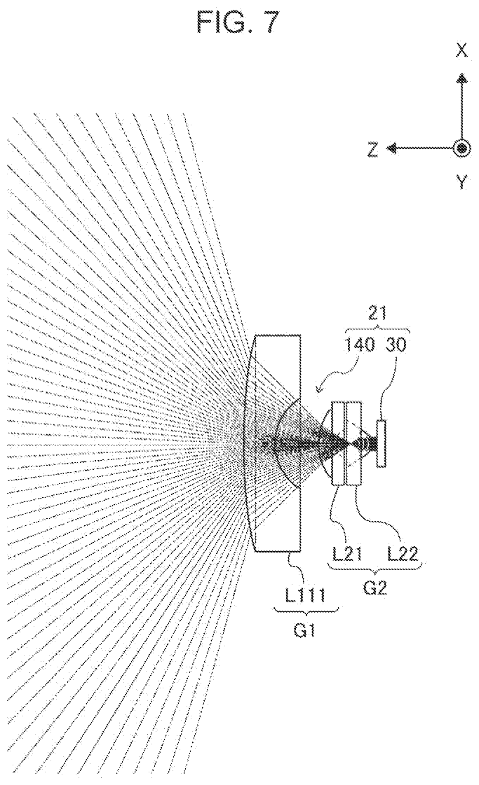

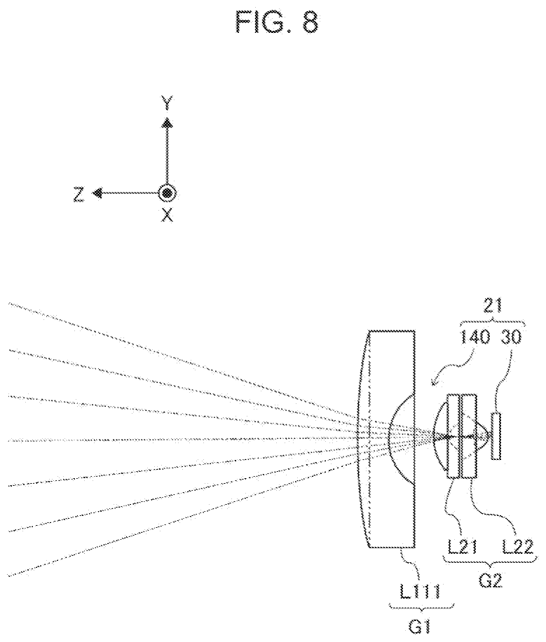

The light exit area of the VCSEL array 30 is also smaller in the Y-axis direction than in the X-axis direction. For clearer understanding of the characteristics of the optical system 40, FIGS. 7 and 8 show an example in which only the lens L11 of the first lens group G1 in the optical system 40 shown in FIGS. 5 and 6 is changed to a lens L111 having equal refractive powers in the X-axis direction and in the Y-axis direction. FIG. 7 is an X-Z plane projection showing the configuration of an optical system 140 having equal refractive powers in the X-axis direction and in the Y-axis direction. FIG. 8 is a Y-Z plane projection showing the configuration of the optical system 140 having equal refractive powers in the X-axis direction and in the Y-axis direction.

Although the original light exit area of the VCSEL array 30 is smaller in the Y-axis direction than in the X-axis direction, in each light emitting region B, the light exit area is smaller in the X-axis direction than in the Y-axis direction. However, through the comparison between FIGS. 5, 6 and FIGS. 7, 8, it can be understood that, in the light emitting device 21, regardless of the configuration of the VCSEL array 30, the amount of light diffused in the Y-axis direction is reduced, compared with a case where an optical system having equal refractive powers in the X-axis direction and in the Y-axis direction is used.

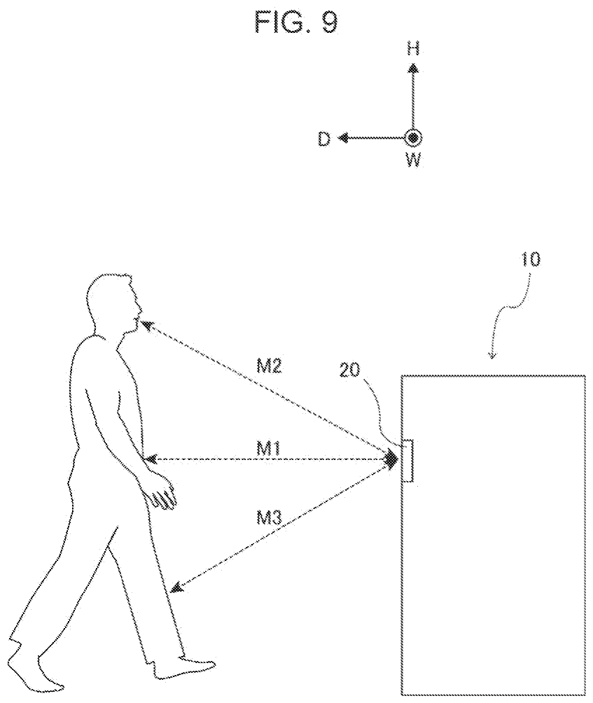

Next, FIG. 9 shows the effect of the optical distance-measuring device 20 according to this exemplary embodiment. When the optical distance-measuring device 20 detects, with light, a user who is going to use the image forming apparatus 10, because the shape of the user to be detected has a greater length in the vertical direction and a smaller length in the horizontal direction, if the light is diffused over a wide area in the Y-axis direction, multiple optical paths having different optical path lengths may be produced for a single object to be measured. The optical path length between the optical distance-measuring device 20 and the object to be measured increases as the light exit angle increases, in other words, as the inclination with respect to the horizontal direction increases. Furthermore, because the user substantially stands on the same floor as the floor on which the image forming apparatus 10 is installed, it is only necessary to detect the presence of the user in the horizontal direction.

For example, in the example in FIG. 9, the optical path lengths of light M2 and M3 exiting at an angle with respect to the horizontal direction are greater than the optical path length of light M1 exiting in the horizontal direction. With this situation, the optical distance-measuring device cannot accurately measure the distance to the object to be measured.

In contrast, because the optical distance-measuring device 20 according to this exemplary embodiment has the light emitting device 21, in which the amount of light diffused in the Y-axis direction is reduced, only light having a small exit angle with respect to the horizontal direction is emitted. Hence, the optical distance-measuring device 20 according to this exemplary embodiment has a higher measuring precision than an optical distance-measuring device having a light emitting device provided with an optical system in which the light exit angle in the X-axis direction and that is the Y-axis direction are equal.

Furthermore, in the image forming apparatus 10 according to this exemplary embodiment, the light emitting device 21 of the optical distance-measuring device 20 is disposed such that the X-axis direction thereof corresponds to the horizontal direction of the image forming apparatus 10, and the Y-axis direction thereof corresponds to the vertical direction of the image forming apparatus 10.

Hence, it is possible to measure an object to be measured in the vicinity of the image forming apparatus 10 over a wider area in the horizontal direction than in the case where the light emitting device 21 of the optical distance-measuring device 20 is disposed such that the X-axis direction thereof corresponds to the vertical direction of the image forming apparatus 10.

### Modification of First Embodiment

The configuration of the optical distance-measuring device 20 according to this exemplary embodiment is not limited to the one described above.

For example, the detector is not limited to the PD 22, but may be anything that can detect light, such as a photomultiplier.

Furthermore, the light emitting elements 32 on the substrate 31 of the VCSEL array 30 do not necessarily have to be arranged in a staggered pattern as described above, but may be arranged in any pattern, such as matrix.

Furthermore, the multiple light emitting elements 32 in each light emitting region B do not necessarily have to be arranged such that the number of the light emitting elements 32 in the Y-axis direction is greater than the number of the light emitting elements 32 in the X-axis direction as described above, but may be arranged in any pattern, such as a pattern in which the number of the light emitting elements 32 in the X-axis direction and the number of the light emitting elements 32 in the Y-axis direction are equal.

Furthermore, the light emitting part is not limited to the VCSEL array 30, but may be anything that emits light, such as an LED array or the like.

### Second Exemplary Embodiment

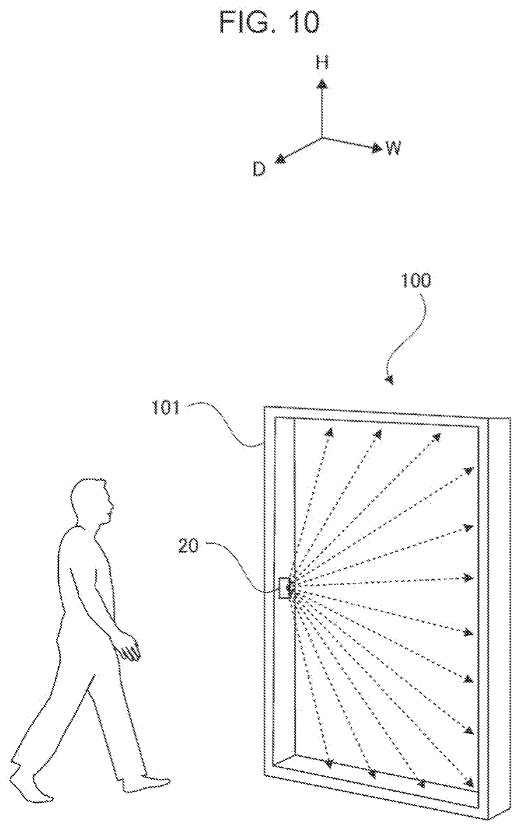

Next, FIG. 10 is an external view schematically showing the configuration of a human sensing gate 100 according to a second exemplary embodiment of the present disclosure. The W, H, and D axes in FIG. 10 are coordinate axes of the human sensing gate 100. The W-axis direction is the horizontal direction corresponding to the width direction of the apparatus, the H-axis direction is the vertical direction corresponding to the top-bottom direction of the apparatus, and the D-axis direction is the horizontal direction corresponding to the depth direction of the apparatus.

As shown in FIG. 10, the human sensing gate 100 is a device for detecting a human passing through a frame 101. An optical distance-measuring device 20, serving as a human sensor for sensing a human passing through the frame 101, is provided on the inner surface of the frame 101.

The human sensing gate 100 according to this exemplary embodiment detects entry and exit of a person to and from a facility or a site provided with the human sensing gate 100 by, for example, detecting a person passing through the frame 101 with the optical distance-measuring device 20.

Because the configuration of the optical distance-measuring device 20 is the same as that according to the first exemplary embodiment, the description thereof will be omitted.

The optical distance-measuring device 20 is disposed inside the frame 101 of the human sensing gate 100 such that the X-axis direction thereof corresponds to the vertical direction of the human sensing gate 100, and the Y-axis direction thereof corresponds to the horizontal direction of the human sensing gate 100.

With this configuration, in the human sensing gate 100, it is possible to radiate the measuring light over a wider area in the frame 101, compared with a case where the X-axis direction of the optical distance-measuring device 20 corresponds to the horizontal direction of the human sensing gate 100, and the Y-axis direction corresponds to the vertical direction of the human sensing gate 100. Thus, it is possible to suppress failure to detect a person passing through the human sensing gate 100.

### Examples

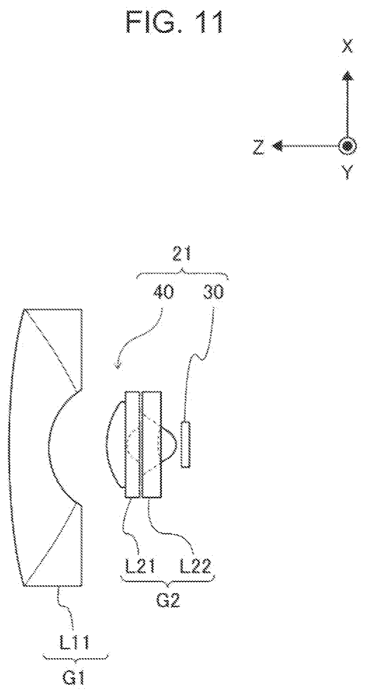

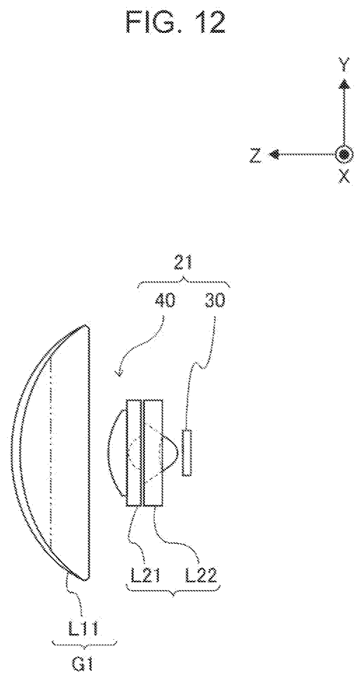

Next, examples of the optical system of the light emitting device of the present disclosure will be described. First, the optical system 40 of Example 1 will be described. FIG. 11 is an X-Z plane projection showing the configuration of the optical system 40 of Example 1, and FIG. 12 is a Y-Z plane projection showing the configuration of the optical system 40 of Example 1. In FIGS. 11 and 12, the left side corresponds to the light exit side, and the right side corresponds to the light entrance side. FIGS. 11 and 12 show the position of the VCSEL array 30 with respect to the optical system 40 and do not accurately show the size and shape of the VCSEL array 30.

The optical system 40 of Example 1 includes, in order from the light exit side to the light entrance side, a first lens group G1 and a second lens group G2 arranged along an optical axis parallel to the Z-axis direction. The largest air spacing in the optical system is provided between the first lens group G1 and the second lens group G2.

The first lens group G1 includes a single lens, L11. The light-exit-side surface of the lens L11 has a toroidal shape, and the light-entrance-side surface of the lens L11 has a cylindrical shape. The lens L11 has a negative refractive power in the X-axis direction and a positive refractive power in the Y-axis direction. In other words, the first lens group G1 has an anisotropic light-transmission property.

The second lens group G2 includes two lenses, namely, lenses L21 and L22, in order from the light exit side to the light entrance side. The second lens group G2 is configured to have, as a whole, equal refractive powers in the X-axis direction and in the Y-axis direction. In other words, the second lens group G2 has an isotropic light-transmission property.

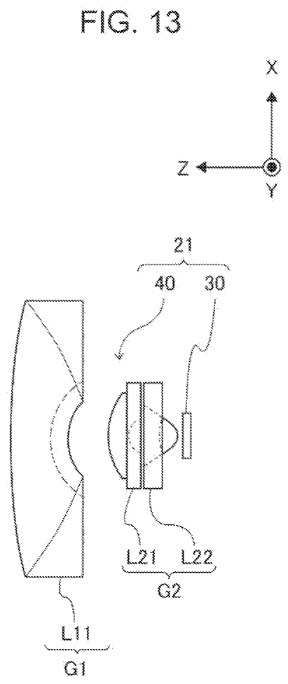

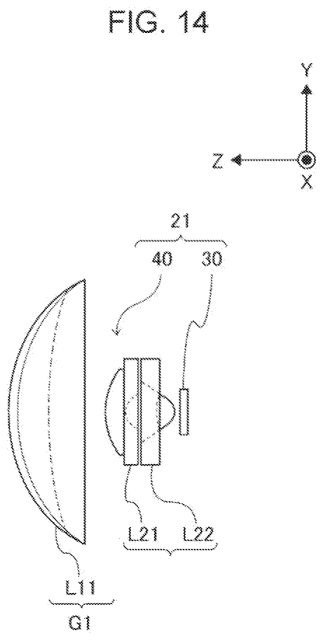

Next, the optical system 40 of Example 2 will be described. FIG. 13 is an X-Z plane projection showing the configuration of the optical system 40 of Example 2, and FIG. 14 is a Y-Z plane projection showing the configuration of the optical system 40 of Example 2. In FIGS. 13 and 14, the left side corresponds to the light exit side, and the right side corresponds to the light entrance side. FIGS. 13 and 14 show the position of the VCSEL array 30 with respect to the optical system 40 and do not accurately show the size and shape of the VCSEL array 30.

The optical system 40 of Example 2 includes, in order from the light exit side to the light entrance side, a first lens group G1 and a second lens group G2 arranged along an optical axis parallel to the Z-axis direction. The largest air spacing in the optical system is provided between the first lens group G1 and the second lens group G2.

The first lens group G1 includes a single lens, L11. The light-exit-side surface and the light-entrance-side surface of the lens L11 both have a toroidal shape. The lens L11 has a negative refractive power in the X-axis direction and a positive refractive power in the Y-axis direction. In other words, the first lens group G1 has an anisotropic light-transmission property.

The second lens group G2 includes two lenses, namely, lenses L21 and L22, in order from the light exit side to the light entrance side. The second lens group G2 is configured to have, as a whole, equal refractive powers in the X-axis direction and in the Y-axis direction. In other words, the second lens group G2 has an isotropic light-transmission property.

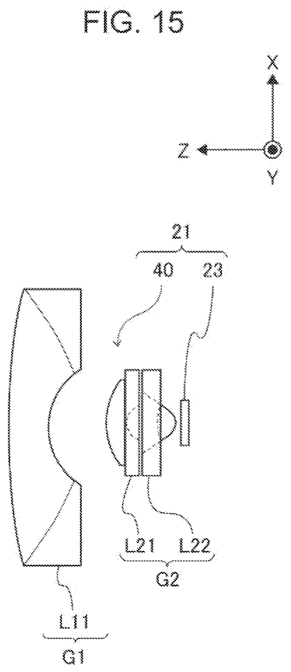

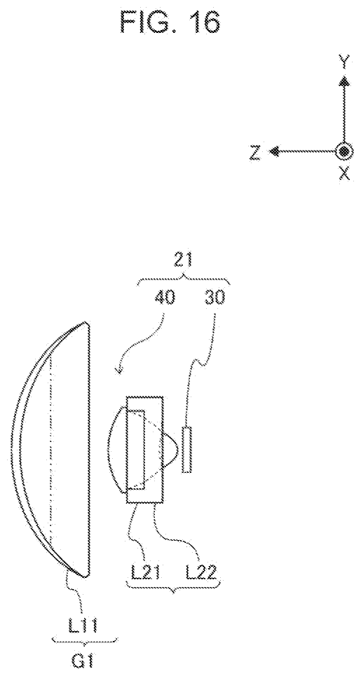

Next, the optical system 40 of Example 3 will be described. FIG. 15 is an X-Z plane projection showing the configuration of the optical system 40 of Example 3, and FIG. 16 is a Y-Z plane projection showing the configuration of the optical system 40 of Example 3. In FIGS. 15 and 16, the left side corresponds to the light exit side, and the right side corresponds to the light entrance side. FIGS. 15 and 16 show the position of the VCSEL array 30 with respect to the optical system 40 and do not accurately show the size and shape of the VCSEL array 30.

The optical system 40 of Example 3 includes, in order from the light exit side to the light entrance side, a first lens group G1 and a second lens group G2 arranged along an optical axis parallel to the Z-axis direction. The largest air spacing in the optical system is provided between the first lens group G1 and the second lens group G2.

The first lens group G1 includes a single lens, L11. The light-exit-side surface of the lens L11 has a toroidal shape, and the light-entrance-side surface of the lens L11 has a cylindrical shape. The lens L11 has a negative refractive power in the X-axis direction and a positive refractive power in the Y-axis direction. In other words, the first lens group G1 has an anisotropic light-transmission property.

The second lens group G2 includes two lenses, namely, lenses L21 and L22, in order from the light exit side to the light entrance side. The second lens group G2 has, as a whole, a negative refractive power in the X-axis direction and a positive refractive power in the Y-axis direction. In other words, the second lens group G2 has an anisotropic light-transmission property.

Next, the results of optical-path-length evaluation simulation with the optical systems 40 in Examples 1 to 3 will be described. The results with the comparison example having a related-art configuration will also be shown to compare to Examples 1 to 3.

The optical system in the comparison example is the same as the optical system 40 of Example 1, except that only the lens L11 in the first lens group G1 is changed to a lens having equal refractive powers in the X-axis direction and in the Y-axis direction.

Now, details of the optical-path-length evaluation simulation will be described. In the optical-path-length evaluation simulation, the going/returning distance traveled by a ray emitted from a specific segmented block of the VCSEL array, reflected by a target surface disposed at a specific position, and returning to a light-receiving PD is measured as the optical path length. The ray tracking simulation in the optical-path-length evaluation simulation is performed by using the Monte Carlo method, in which several millions to several hundreds of millions of rays are randomly emitted from a light source under the constraint conditions.

More specifically, six light emitting regions B1 to B6 are defined along the X-axis direction in the VCSEL array, and rays emitted from each light emitting region, reflected by the target surface disposed at a position 150 mm away, in a straight line, from the center of the VCSEL array, and returning to the light-receiving PD are measured.

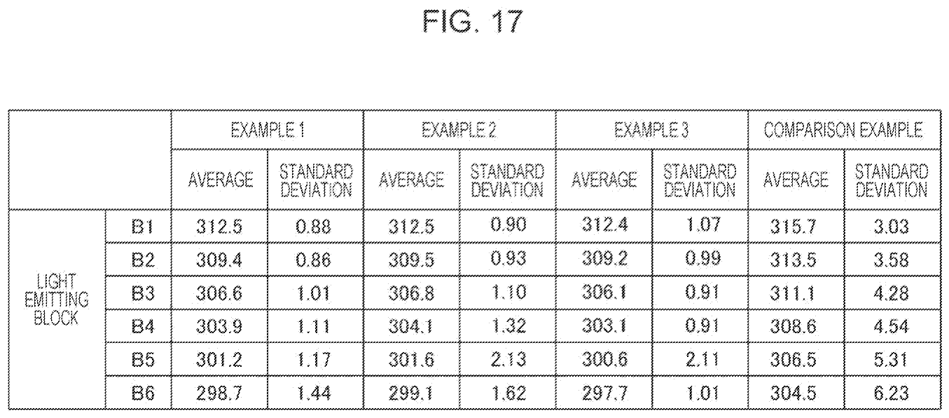

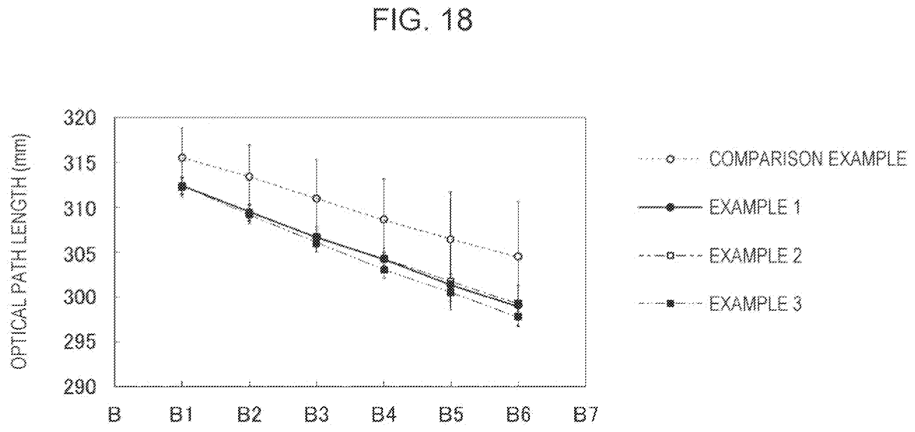

FIG. 17 is a table of average and standard deviation of measurement results for the respective light emitting regions in Examples 1 to 3 and in the comparison example. FIG. 18 is a graph plotted from the table in FIG. 17. In the graph in FIG. 18, the horizontal axis represents the position of the light emitting regions, and the vertical axis represents the optical path length.

It is understood from FIGS. 17 and 18 that, compared with the results in the comparison example, the results in Examples 1 to 3 are close to the preset distance in all the light emitting regions, and also, the standard deviations are small.

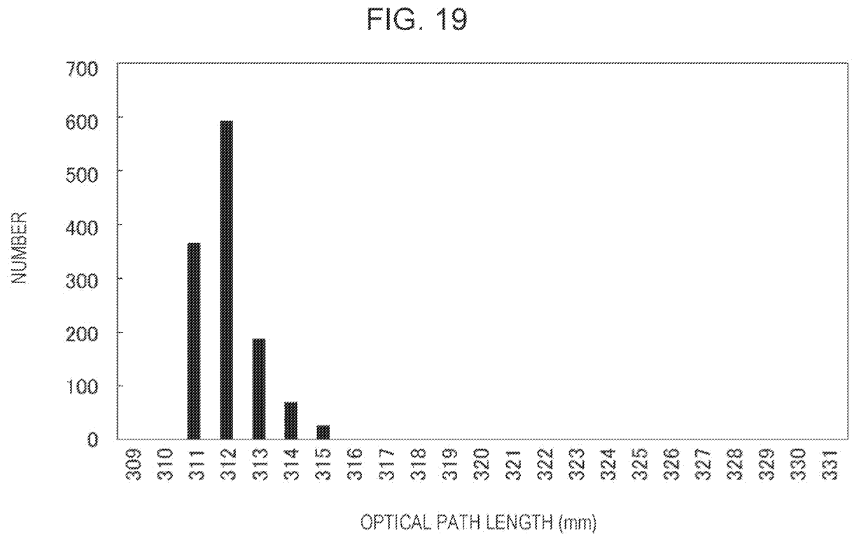

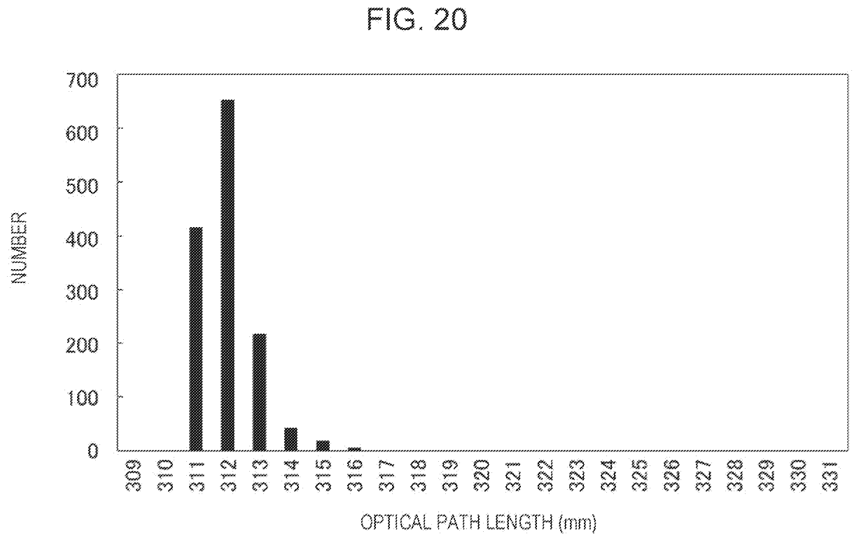

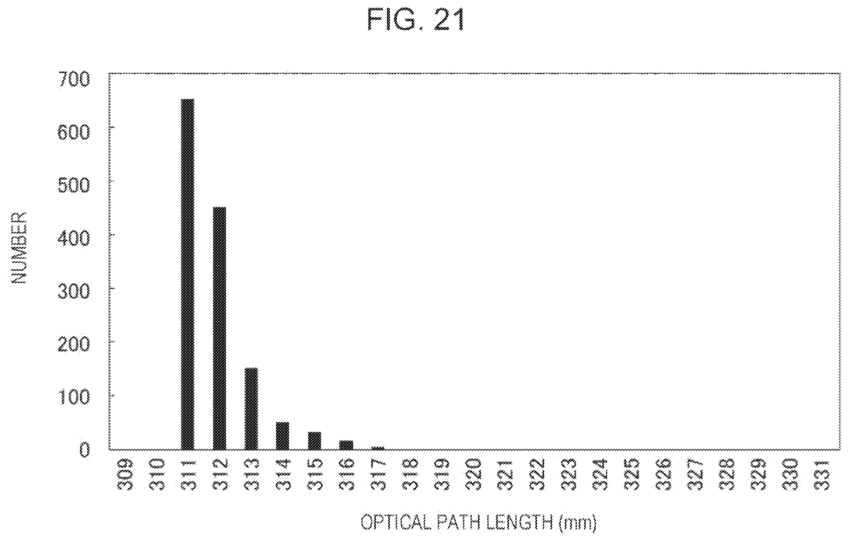

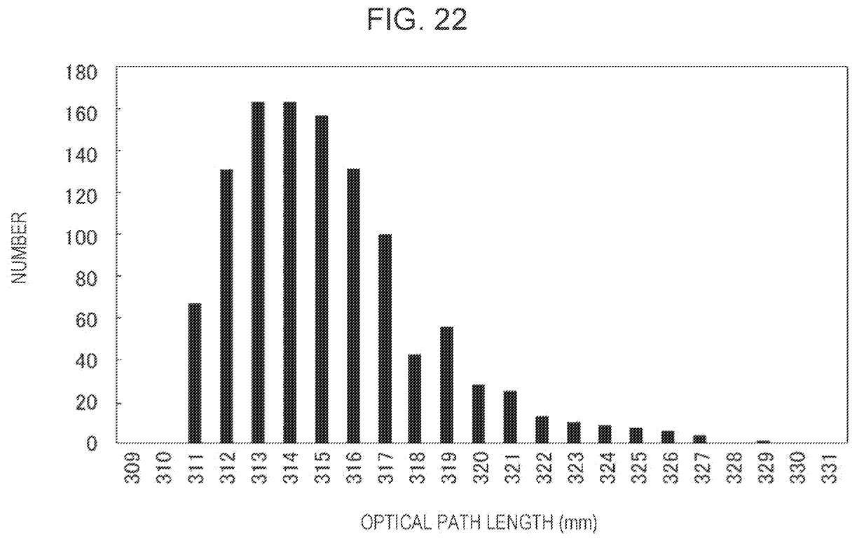

FIGS. 19 to 22 are graphs showing the number of rays for each of the total optical path lengths of the six light emitting regions B1 to B6 in Examples 1 to 3 and in the comparison example. In FIGS. 19 to 22, the horizontal axis of the graph represents the optical path length, and the vertical axis of the graph represents the number of rays. FIG. 19 is a graph showing the simulation result with Example 1, FIG. 20 is a graph showing the simulation result with Example 2, FIG. 21 is a graph showing the simulation result with Example 3, and FIG. 22 is a graph showing the simulation result with the comparison example.

It is understood from FIGS. 19 to 22 that, in all the results with Examples 1 to 3, the rays concentrate on optical path lengths close to the preset distance, compared with the results in the comparison example.

### Modification

In the above-described exemplary embodiments, the cases where the present disclosure is applied to the image forming apparatus 10 and where the present disclosure is applied to the human sensing gate 100 have been described. However, the application of the present disclosure is not limited to such cases, and the present disclosure may also be applied to information processing apparatuses, such as automatic teller machines (ATM) and ticket machines, that are approached and operated by users, or to devices, such as self-propelled automatic guided vehicles and robot vacuum cleaners, that detect obstacles.

The foregoing description of the exemplary embodiments of the present disclosure has been provided for the purposes of illustration and description. It is not intended to be exhaustive or to limit the disclosure to the precise forms disclosed. Obviously, many modifications and variations will be apparent to practitioners skilled in the art. The embodiments were chosen and described in order to best explain the principles of the disclosure and its practical applications, thereby enabling others skilled in the art to understand the disclosure for various embodiments and with the various modifications as are suited to the particular use contemplated. It is intended that the scope of the disclosure be defined by the following claims and their equivalents.

### APPENDIX

Configurations of the present disclosure are appended below.

(((1)))

A light emitting device including: a light emitting part having multiple light emitting regions arranged along a first direction; and an optical system that is disposed on a light-exit side of the light emitting part and that deflects light emitted from the multiple light emitting regions in different directions, the optical system being configured such that a light exit angle in a second direction, which intersects the first direction, is smaller than the light exit angle in the first direction.

(((2)))

The light emitting device according to (((1))), wherein multiple light emitting elements are provided in each light emitting region of the light emitting part, and, in each light emitting region, the number of the light emitting elements in the second direction is greater than that in the first direction.

(((3)))

The light emitting device according to (((2))), wherein the length of each light emitting region in the second direction is greater than that in the first direction.

(((4)))

The light emitting device according to (((3))), wherein the length of the entirety of the multiple light emitting regions of the light emitting part in the first direction is greater than that in the second direction.

(((5)))

The light emitting device according to any one of (((1))) to (((4))), wherein the optical system includes a lens having a toroidal surface that has different curvature in the first direction and in the second direction, the radius of curvature in the second direction being smaller than that in the first direction.

(((6)))

The light emitting device according to any one of (((1))) to (((5))), wherein the optical system includes a lens having a cylindrical surface that has curvature in the first direction and no curvature in the second direction.

(((7)))

The light emitting device according to any one of (((1))) to (((6))), wherein the optical system includes, in order from a light exit side to a light entrance side, a first lens group and a second lens group, a largest air spacing is provided between the first lens group and the second lens group, and the first lens group has, as a whole, a negative refractive power in the first direction and a positive or no refractive power in the second direction.

(((8)))

The light emitting device according to (((7))), wherein the first lens group includes a single lens, an exit-side surface of the lens having a toroidal shape, and an entrance-side surface of the lens having a cylindrical shape.

(((9)))

The light emitting device according to (((7))), wherein the first lens group includes a single lens, an exit-side surface and an entrance-side surface of the lens having toroidal shapes.

(((10)))

The light emitting device according to any one of (((7))) to (((9))), wherein the second lens group has, as a whole, a negative refractive power in the first direction and a positive or no refractive power in the second direction.

(((11)))

The light emitting device according to any one of (((7))) to (((9))), wherein the second lens group has, as a whole, equal refractive powers in the first direction and in the second direction.

(((12)))

The light emitting device according to any one of (((7))) to (((11))), wherein the first lens group includes a single lens, and the second lens group includes two lenses.

(((13)))

An optical distance-measuring device including the light emitting device according to any one of (((1))) to (((12))), and a detector that detects reflected light of the light emitted from the light emitting device.

(((14)))

An image forming apparatus including the optical distance-measuring device according to (((13))), wherein the light emitting device is disposed such that the first direction corresponds to the horizontal direction, and the second direction corresponds to the vertical direction.

What is claimed is:

1. A light emitting device comprising:
a light emitting part having multiple light emitting regions arranged along a first direction; and
an optical system that is disposed on a light-exit side of the light emitting part and that deflects light emitted from the multiple light emitting regions in different directions, the optical system being configured such that a light exit angle in a second direction, which intersects the first direction, is smaller than the light exit angle in the first direction.

2. The light emitting device according to claim 1, wherein multiple light emitting elements are provided in each light emitting region of the light emitting part, and, in each light emitting region, the number of the light emitting elements in the second direction is greater than the number of the light emitting elements in the first direction.

3. The light emitting device according to claim 2, wherein the length of each light emitting region in the second direction is greater than the length of each light emitting region in the first direction.

4. The light emitting device according to claim 3, wherein the length of the entirety of the multiple light emitting regions of the light emitting part in the first direction is greater than the length of the entirety of the multiple light emitting regions of the light emitting part in the second direction.

5. The light emitting device according to claim 1, wherein the optical system includes a lens having a toroidal surface that has different curvature in the first direction and in the second direction, a radius of curvature of the toroidal surface in the second direction being smaller than the radius of curvature of the toroidal surface in the first direction.

6. The light emitting device according to claim 1, wherein the optical system includes a lens having a cylindrical surface that has curvature in the first direction and no curvature in the second direction.

7. The light emitting device according to claim 1, wherein
the optical system includes, in order from a light exit side to a light entrance side, a first lens group and a second lens group,
a largest air spacing is provided between the first lens group and the second lens group, and
the first lens group has, as a whole, a negative refractive power in the first direction and a positive or no refractive power in the second direction.

8. The light emitting device according to claim 7, wherein the number of lenses included in the first lens group is one, an exit-side surface of the one lens has a toroidal shape, and an entrance-side surface of the one lens has a cylindrical shape.

9. The light emitting device according to claim 7, wherein the number of lenses included in the first lens group is one, and an exit-side surface and an entrance-side surface of the one lens have toroidal shapes.

10. The light emitting device according to claim 7, wherein the second lens group has, as a whole, a negative refractive power in the first direction and a positive or no refractive power in the second direction.

11. The light emitting device according to claim 7, wherein the second lens group has, as a whole, equal refractive powers in the first direction and in the second direction.

12. The light emitting device according to claim 7, wherein the number of lenses included in the first lens group includes is one, and the number of lenses included in the second lens group is two.

13. An optical distance-measuring device comprising:
the light emitting device according to claim 1; and
a detector that detects reflected light of the light emitted from the light emitting device.

14. An optical distance-measuring device comprising:
the light emitting device according to claim 2; and
a detector that detects reflected light of the light emitted from the light emitting device.

15. An optical distance-measuring device comprising:
the light emitting device according to claim 3; and
a detector that detects reflected light of the light emitted from the light emitting device.

16. An optical distance-measuring device comprising:
the light emitting device according to claim 4; and
a detector that detects reflected light of the light emitted from the light emitting device.

17. An optical distance-measuring device comprising:
the light emitting device according to claim 5; and
a detector that detects reflected light of the light emitted from the light emitting device.

18. An optical distance-measuring device comprising:
the light emitting device according to claim 6; and
a detector that detects reflected light of the light emitted from the light emitting device.

19. An optical distance-measuring device comprising:
the light emitting device according to claim 7; and
a detector that detects reflected light of the light emitted from the light emitting device.

20. An image forming apparatus comprising the optical distance-measuring device according to claim 13, wherein the light emitting device is disposed such that the first direction corresponds to the horizontal direction, and the second direction corresponds to the vertical direction.
